(19) United States
(12) Patent Application Publication
(10) Pub. No.: US 2004/0256630 A1
(43) Pub. Date: Dec. 23, 2004

(54) Illuminating light

(76) Inventor: Densen Cao, Sandy, UT (US)

Correspondence Address: Parsons Behle & Latimer, Suite 1800, 201 South Main Street, P.O. Box 45898, Salt Lake City, UT, 84111, US

(21) Appl. No.: 10/773,123

(22) Filed: Feb. 5, 2004

Related U.S. Application Data
(63) Continuation-in-part of application No. 09/939,339, filed on Aug. 24, 2001.

(51) Int. Cl. H01L 21/00; H01L 33/00

(52) U.S. Cl. 257/98; 257/99; 257/100; 438/25; 438/27

(57) ABSTRACT

An illuminating light for illuminating a physical space for use by humans has been invented. In one example the illuminating light includes at least one semiconductor chip that can emit light mounted to a primary heat sink. The primary heat sink is mounted to a secondary heat sink and a heat sink grid is provided to dissipate heat to the atmosphere. Other examples are also disclosed.

### CROSS REFERENCE TO RELATED APPLICATIONS

This patent application is a continuation-in-part of U.S. patent application Ser. No. 09/939,339 filed Aug. 24, 2001, and priority is claimed thereto. The disclosure of that prior patent application is hereby incorporated by reference in its entirety.

### I. BACKGROUND

This disclosure relates to the field of illuminating lights, particularly lights that employ semiconductor light sources, which provide lighting of a visible nature in order to illuminate a physical space for use by humans.

### II. SUMMARY

Illuminating lights are described that are capable of illuminating a space with visible light. The disclosed illuminating lights tend to produce less heat, use less energy, and provide more intense light than many lights currently on the market.

### III. BRIEF DESCRIPTION OF THE DRAWINGS

FIG. 1 depicts a perspective view of an example semiconductor light source.

FIGS. 2a and 2b depict cross sectional views of example illuminating lights.

FIGS. 3a and 3b depict example semiconductor light sources in packaged configuration with a heat sink and dome that may be used in illuminating lights.

FIG. 4 depicts a block diagram of example electrical control for an illuminating light.

### IV. DETAILED DESCRIPTION

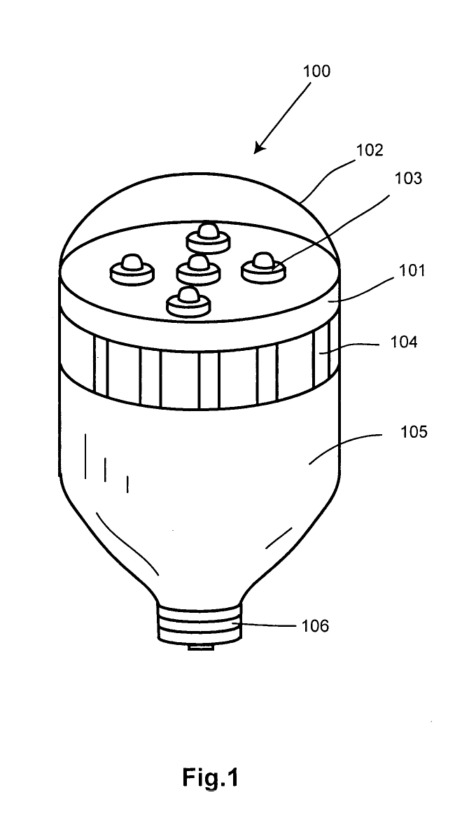

Referring to FIG. 1, an example illuminating light 100 is depicted. The illuminating light 100 includes a connection knob 106 for establishing both mechanical mounting to and positive and negative electrical connection with a light socket. A casing 105 is provided that may contain or provide support for other components of the illuminating light 100.

A heat sink grid 104 is provided to dissipate heat that has been drawn away from semiconductor light sources. The heat sink grid 104 may include fins or other surface texturing to increase its surface area, promote air flow, and/or dissipate heat. A secondary heat sink 101 is provided that serves as a mounting location for semiconductor light sources or semiconductor light source modules. The secondary heat sink 101 also serves to draw heat away from semiconductor light sources or semiconductor light sources modules and any primary heat sinks that they may include. The heat sink grid 104 is located on the proximal side of the secondary heat sink 101. The secondary heat sink 101 also serves to communicate heat to the heat sink grid 104 where the heat may be dissipated. The secondary heat sink 101 and heat sink grid 104 may be a single integral component, such as machined, extruded or cast meta or formed ceramic, or they may be separate physical components that are assembled together in a heat-transferring relationship. That heat transferring relationship may include direct mechanical contact between secondary heat sink 101 and heat sink grid 104, or there may be components located in between them as long has heat conductance between secondary heat sink 101 and heat sink grid 104 is maintained.

On the proximal side of secondary heat sink 101, one or more semiconductor light sources 103 are mounted. A cover 102 covers the light sources 103 and may be affixed to the secondary heat sink 101 or the casing 105. The cover 103 may be of any desired shape, including spherical, cylindrical, elliptical, domed, square, n-sided where n is an integer, or otherwise. The cover may be made from any desired light transparent or translucent materials, including glass, plastic, polycarbonate, and other light transparent materials. The cover 103 may be smooth and glossy, matte, or another finish or texture. The cover 103 may be coated or painted with desired materials. The cover 103 optionally include an appropriate coating, such as a luminous powder coating. Examples of luminous powder coating that may be used in the invention include YAG: Ce or other phosphor powders or coatings. For example, if the light source uses blue LED's to generate light, but it is desired to illuminate a room with white light, the cover may be covered with a phosphor coating to convert blue light into white light. Any wavelength-modifying coating such as phosphor or another coating may be used. In some configurations, it may be intended to convert light emitted by a semiconductor chip in the wavelength range of about 200 to about 700 nm. to white light.

The cover 103 encloses its interior volume which may be a vacuum, or may contain a gas such as ordinary air, an inert gas such as argon or nitrogen, or any other desired gas. In some embodiments of the invention, a gas will be included within the interior volume for the purpose of avoiding oxidation of the heat sink and the semiconductor.

The casing 105 may be of a non-conducting material, such as plastic, to insulate a human hand from electrical shock. The secondary heats sink 101 may have a flat or planar distal side on which the light source(s) 103 are mounted, or it may have a curved or radiused distal side, or a distal side with desired geographic features. The semiconductor light sources 103 may be packaged or non-packaged semiconductors that emit light when provided with electrical power. Example semiconductor light sources include light emitting diodes (LED's), LED arrays, vertical cavity surface emitting laser (VCSEL's), VCSEL arrays, photon recycling devices that cause a monochromatic chip to emit white light, and others, in any desired configuration. Direct mount, surface mount, flip chip and any other desired chip mounting configuration may be employed.

In order to provide suitable electrical power to the semiconductor devices, an AC/DC converter (not shown in this fixture) may be utilized. This will permit the invented semiconductor light source to be powered by 110 volt. or 220 volt AC power found in homes and businesses throughout the world. The AC/DC converter may be located in the knob 106, in the casing 105, or in another location.

The secondary heat sink 101 and any other heat sinks in the illuminating light may be any material capable of conducting heat away from the semiconductor light sources. The heat sink(s) may be of a single material or a combination of two different kinds of materials, the first with a low thermal expansion rate and the second with high thermal conductivity. Monolithic heat sinks may be used as well. Examples of some heat sink materials which may be used in lights depicted herein include ceramic, powdered metal, copper, aluminum, silver, magnesium, steel, silicon carbide, boron nitride, tungsten, molybdenum, cobalt, chrome, Si, SiO₂, SiC, AlSi, AlSiC, natural diamond, monocrystalline diamond, polycrystalline diamond, polycrystalline diamond compacts, diamond deposited through chemical vapor deposition and diamond deposited through physical vapor deposition, and composite materials or compounds. Any materials with adequate heat conductance and/or dissipation properties can be used.

Mounting of any semiconductor chip or light module may be achieved by a variety of methods, including mechanical fixation (clips, press-fit, screws, rivets, etc.), brazing, welding, use of an adhesive or other methods. Use of a heat conductive and/or electrically insulative adhesive may be desired. Examples of heat conductive and/or electrically insulative adhesives which may be used are silver based epoxy, other epoxies, and other adhesives with a heat conductive quality and/or electrically insulative quality. In order to perform a heat conductive function, it is important that the adhesive possess the following characteristics: (i) strong bonding between the materials being bonded, (ii) adequate heat conductance, (iii) electrically insulative or electrically conductive if desired (or both), and (iv) light reflectivity if desired, or any combination of the above. Examples of light reflective adhesives which may be used include silver and aluminum based epoxy. One example heat conductive and electrically insulative adhesive includes a mixture of a primer and an activator. In this example, the primer may contain one or more heat conductive agents such as aluminum oxide (about 20-60%) and/or aluminum hydroxide (about 15-50%). The primer may also contain one or more bonding agents such as polyurethane methacrylate (about 8-15%), and/or hydroxyalkyl methacrylate (about 8-15%). An activator may be mixed with the primer to form an adhesive. The activator may include any desired catalyst, for example n-heptane (about 5-50%), aldheyde-aniline condensate (about 30-35%), isopropyl alcohol (about 15-20%), and an organocopper compound (about 0.01 to 0.1%). Adhesives such as described herein can be used to mount a chip to a primary heat sink, or to mount a primary heat sink to a secondary heat sink, or both.

The semiconductor light sources can include semiconductor chips that emit light when provided with electrical power. The chips may include any of a variety of materials known for constructing chips that emit light. The chips may include a variety of epitaxial layers grown on a substrate. Examples of substrates on which the semiconductors used in the lights depicted herein may be grown include Si, GaAs, GaN, ZnS, ZnSe, InP, Al₂O₃, SiC, GaSb, InAs and others. Both electrically insulative and electrically conductive substrates may be used.

If desired, any of the heat sinks of the illuminating light may include a thermoelectric cooler. A thermoelectric cooler tends to provide a cooling effect when electrically charged, thereby assisting in keeping the light cool, preventing overheating of semiconductors which may decrease their efficiency or life, and prevents the illuminating light from becoming hot enough to danger its surrounding environment. Example materials which may be used in a thermoelectric cooler in illuminating lights include Bi₂Te₃, PbTe, SiGe, BeO₂, BiTeSe, BiTeSb, AlO₃, AlN, BaN and others.

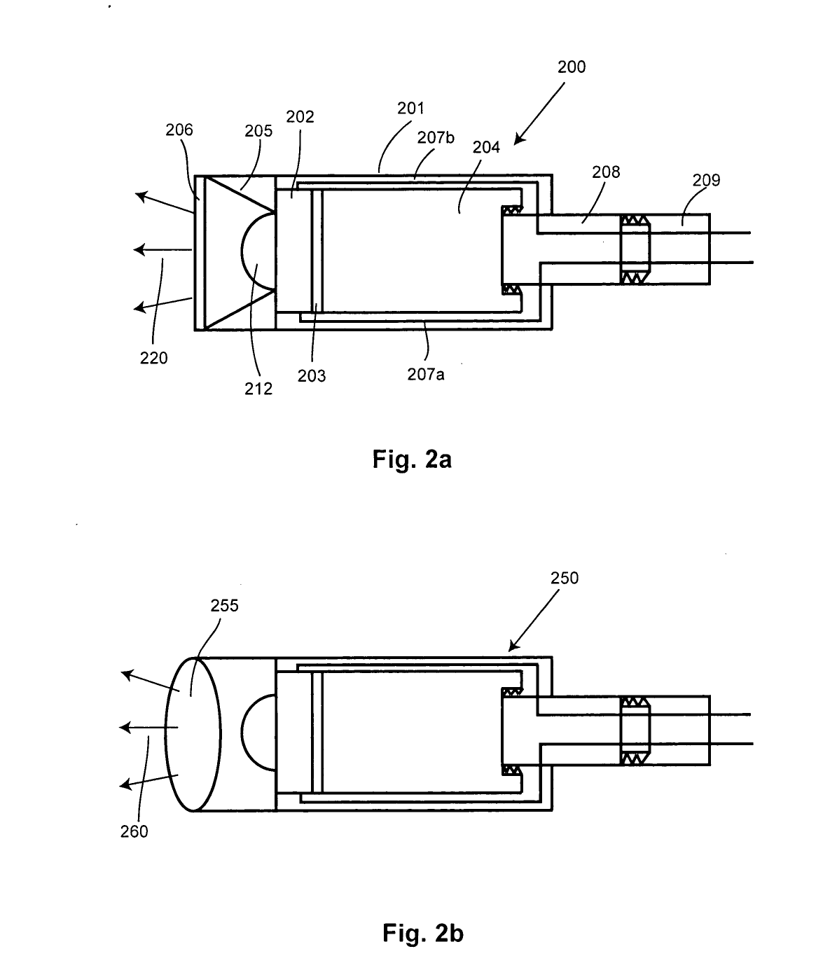

Referring to FIG. 2a, a cross section of an illuminating light 201 is depicted. A connection knob 208 is provided for connecting to a light socket. The connection knob 208 may have located therein positive and negative connection wires 209a and 209b for providing positive and negative electrical connection for operating the illuminating light. A casing 205 is provided as already mentioned. A circuit board 206 may be provided with circuitry for power control and conversion from AC to DC per the control block diagram discussed later herein, or per another appropriate configuration. Electrical conduction wires 207a and 207b provide electrical connection from the circuit board 206 to semiconductor light sources 204a-204d. A secondary heat sink 201 and a heat sink grid 201b, as already mentioned in some detail, are provided. The heat sink grid may be open to the atmosphere exterior to the illuminating light in order to provide airflow therethrough for purposes of heat dissipation. Alternatively, the heat sink grid may be open to the atmosphere exterior to the illuminating light for air contact and heat dissipation purposes without providing airflow therethrough. Semiconductor light sources 202a-202d may be mounted to the distal side of the secondary heat sink 201 via any appropriate method, such as those methods previously mentioned. The semiconductor light sources depicted in this figure are LED packages, each of which includes an LED chip mounted to a primary heat sink, and a dome to cover the LED chip. The primary heat sink is typically either of lesser mass or lesser interior volume or both than the primary heat sink. A cover 204 may be provided that covers the semiconductor light sources if desired.

Referring to FIG. 2b, another example illuminating light 250 is depicted in cross section. Features not specifically described in this paragraph may be as already described herein or otherwise as desired. A secondary heat sink 251 with a heat sink grid 255 on its proximal side are included. The secondary heat sink 251 has a distal side where a plurality of heat sink wells 252 are located. At least some of the wells 252 include mounted therein an appropriate light emitting semiconductor light source such as an LED chip 253. Intermediate islands 255 may be present between wells 252, and wires for electrical conduction may be placed between chips 253 and wires 256. The wells may include a light reflective surface for reflecting light emitted by the chips outward in a useful direction.

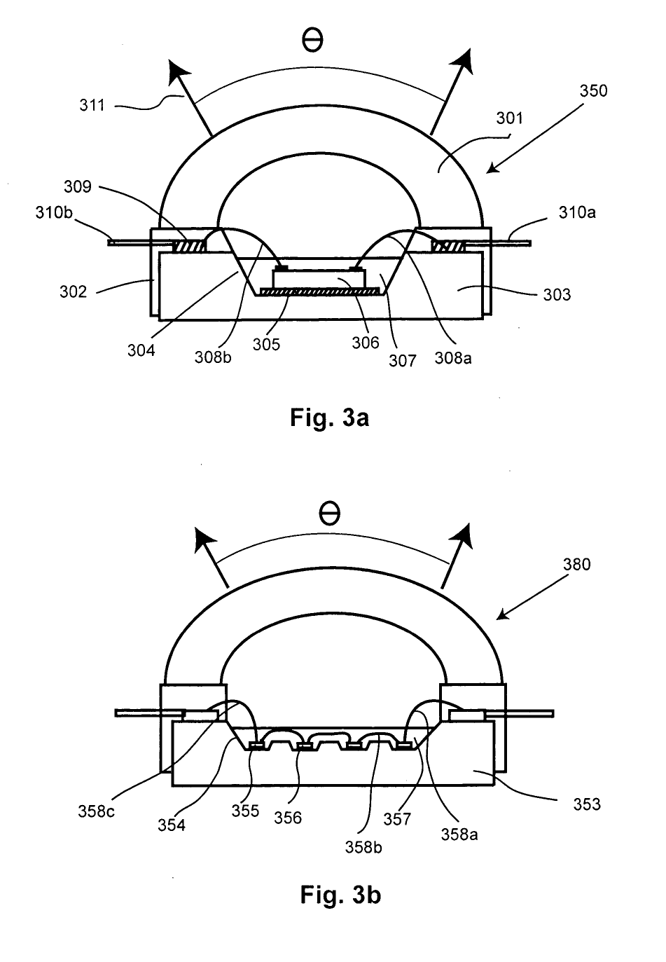

Referring to FIG. 3a, a high power LED package 350 is depicted using a single chip or chip array 306. The chip 306 is mounted in the well 304 of a primary heat sink 303 using heat conductive and light reflective adhesive 305. The primary heat sink may be electrically conductive or electrically insulative as desired. The primary heat sink may be surrounded by a known insulating material 302 that can serves the purpose of electrical insulation. The walls and bottom of the well may be polished to be light reflective, or may be covered, plated, painted or bonded with a light-reflective coating such as Al, Au, Ag, Zn, Cu, Pt, chrome, other metals, plating, plastic and others to reflect light and thereby improve light source efficiency. Electrodes 310a and 310b and/or connection blocks 309 may be provided for electrical connection of the chip 306. Wires 308a and 308b may establish electrical connection between the electrodes and the chip. If desired, a coating 307 may be presented over the chip, such as a phosphor coating to convert light emitted by the chip to white light. The coating may be only on the chip, or may fill or partially fill the well. An optical dome or cover 301 may optionally be provided for the purpose of protecting the chip and its assemblies, and for the purpose of focusing light emitted by the chip. The dome may be made of any of suitable material such as plastic, polycarbonate, epoxy, glass and other suitable materials. The configuration of the well and the dome provide for light emission along an arc of a circle defined by Θ in a desired direction 311. The dome 301 may serve the function of protecting the chip(s) from dirt, moisture, contaminants and mechanical damage. It may also serve the function of focusing light emitted by the chip(s) or otherwise modifying the light beam to a desired configuration or footprint.

FIG. 3b depicts a similar arrangement for a chip package 350 in which the heat sink 353 have multiple sub wells 355 each of which has a chip 356 located within it. Wires 358 provide the chips with power. The sub wells 355 are located within primary well 354. Optionally, a coating 357 may be provided to convert light emitted by the chips to a desired wavelength configuration, such as white light. In this example, the coating covers the chips and fills the sub-wells but only partially fills the primary well.

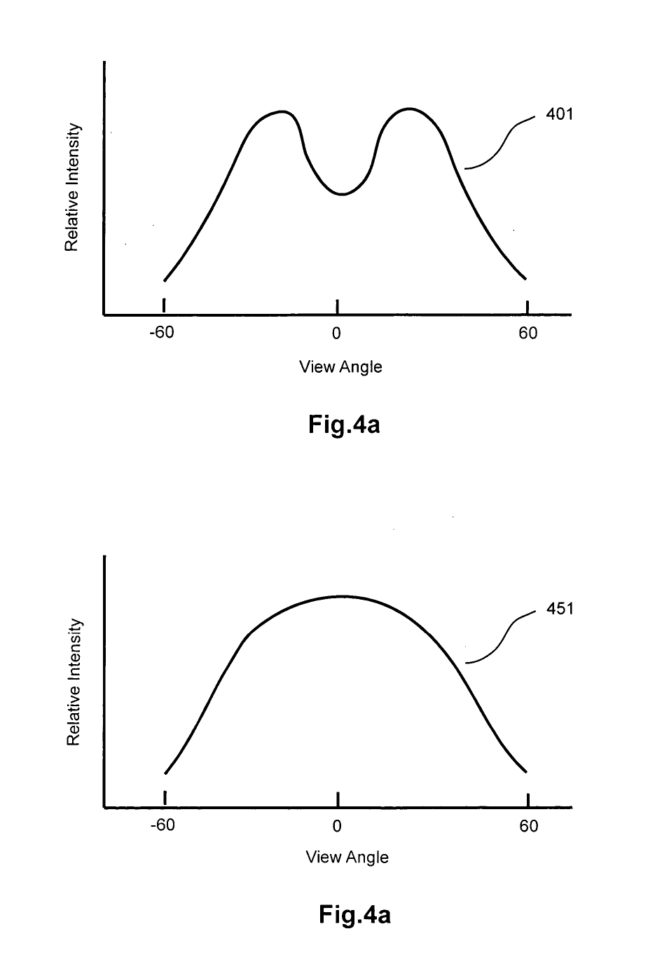

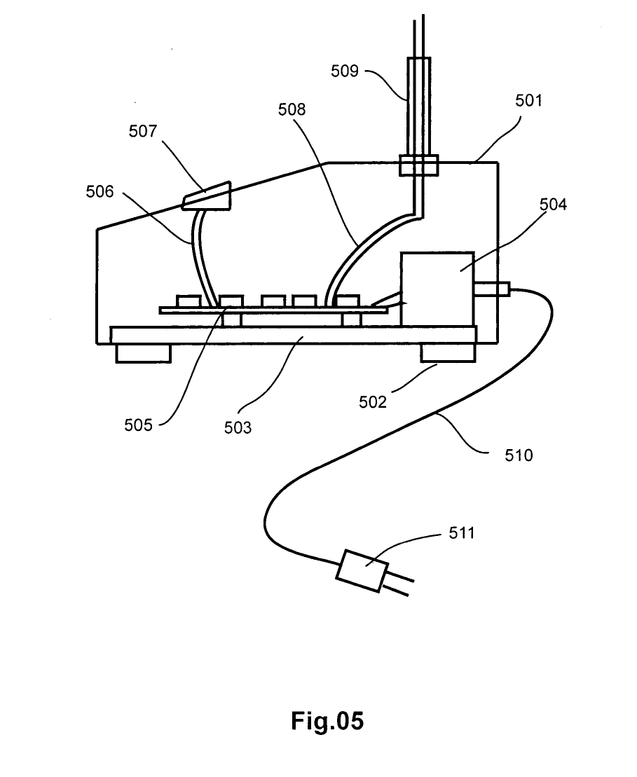

FIG. 4 depicts a block diagram of example circuit control. Input electrical voltage of 110 or 220 volts is provided to a switch power supply 401 and then a constant current source 402 provides electrical power to chips 403.

While devices have been described and illustrated in conjunction with a number of examples, those skilled in the art will appreciate that variations and modifications may be made without departing from the principles of the invention as defined in the appended claims. The invention may be embodied in other specific forms without departing from its spirit or essential characteristics. The described embodiments are considered in all respects to be illustrative and not restrictive. The scope of the invention is, therefore, indicated by the appended claims, rather than by the foregoing description. All changes which come within the meaning and range of equivalence of the claims are to be embraced within their scope.

I claim:

1. An illuminating light comprising:
a connection knob for establishing mechanical and electrical connection to a light socket,
a casing connected to said casing,
a secondary heat sink having a proximal and distal side,
at least one semiconductor light source mounted to said secondary heat sink distal side,
said semiconductor light source including a semiconductor chip mounted to a primary heat sink,
said primary heat sink being mounted to said secondary heat sink,
a heat sink grid located on said secondary heat sink proximal side,
a heat conduction path from said semiconductor chip through said primary heat sink, through said secondary heat sink, to said heat sink grid, and thence to the atmosphere,
said heat sink grid permitting air contact with its surface area in order to dissipate heat to air which contacts it, and
a cover covering said semiconductor light sources.

2. A device as recited in claim 1 further comprising:
a coating on said chip for converting light emitted by said chip to white light.

3. A device as recited in claim 1 further comprising:
a circuit board located within said casing for providing electrical control of the illuminating light.

4. A device as recited in claim 1 wherein said semiconductor light source includes:
a well,
said chip being mounted in said well,
and said coating at least partially filling said well.

5. A device as recited in claim 2 wherein said semiconductor light source includes:
a primary well,
a plurality of sub-wells located in said primary wells,
a plurality of light emitting semiconductor chips located in said sub-wells.

6. A device as recited in claim 5 wherein said coating fills said sub-wells and wherein said coating at least partially fills said sub-wells.

7. A device as recited in claim 1 further comprising a quantity of heat-conductive adhesive that secures said primary heat sink to said secondary heat sink.

8. A device as recited in claim 1 further comprising a quantity of light-reflective adhesive that secures said chip to said primary heat sink.

9. A device as recited in claim 1 further comprising a dome over said primary heat sink, said dome serving to focus light emitted by said chip and direct it in an arc of a circle defined by Θ.

10. A device as recited in claim 1 wherein said primary heat sink has a smaller interior volume than said secondary heat sink.

11. A device as recited in claim 1 wherein said heat sink grid provides for airflow therethrough in order to achieve efficient heat dissipation.

12. An illuminating light comprising:
a semiconductor light source capable of emitting light when electrically powered,
a secondary heat sink having a proximal and distal side,
said semiconductor light source being mounted to said secondary heat sink,
said semiconductor light source including a semiconductor chip mounted to a primary heat sink,
said primary heat sink being mounted to said secondary heat sink,
a heat sink grid located on said secondary heat sink proximal side,
a heat conduction path from said semiconductor chip through said primary heat sink, through said secondary heat sink, to said heat sink grid, and thence to the atmosphere, and
said heat sink grid permitting air contact with its surface area in order to dissipate heat to air which contacts it.

13. A device as recited in claim 12 wherein said semiconductor light source includes a semiconductor chip that emits generally monochromatic light and a coating on said chip to convert light emitted by said chip to white light.

14. A device as recited in claim 13 wherein said semiconductor light source includes:
a well in said primary heat sink,
said chip being mounted in said well, and
and said coating at least partially filling said well.

15. A device as recited in claim 13 wherein said semiconductor light source includes:
a primary well,
a plurality of sub-wells located in said primary wells,
a plurality of light emitting semiconductor chips located in said sub-wells.

16. A device as recited in claim 15 wherein said coating fills said sub-wells and wherein said coating at least partially fills said sub-wells.

17. A device as recited in claim 13 further comprising a quantity of heat-conductive adhesive that secures said primary heat sink to said secondary heat sink.

18. A device as recited in claim 13 further comprising a quantity of light-reflective adhesive that secures said chip to said primary heat sink.

19. A device as recited in claim 13 further comprising a dome over said primary heat sink, said dome serving to focus light emitted by said chip and direct it in an arc of a circle defined by Θ.

20. A device as recited in claim 13 wherein said primary heat sink has a smaller interior volume than said secondary heat sink.

21. A device as recited in claim 13 wherein said heat sink grid provides for airflow therethrough in order to achieve efficient heat dissipation.

22. An illuminating light comprising:
a heat sink having a proximal and a distal side,
at least one semiconductor light source mounted to said heat sink distal side,
said semiconductor light source being in heat conductance with said heat sink,
a heat sink grid located on said heat sink proximal side,
said heat sink grid having a physical configuration that provides substantial surface area for transferring heat to air that passes said heat sink grid, and
a coating for converting light emitted by said semiconductor light source to white light for use in illuminating a physical space used by humans.

23. An illuminating light comprising:
a heat sink having at least two sides,
at least one semiconductor light source mounted to said heat sink and being in heat conductive arrangement therewith,
a heat sink grid located on said heat sink,
said heat sink grid and said semiconductor light source being located on different sides of said heat sink from each other,
said heat sink grid having a physical configuration that provides a non-planar surface area in contact with the atmosphere surrounding the illuminating light for transferring heat from said heat sink grid to air that passes said heat sink grid, and
a coating for converting light emitted by said semiconductor light source to white light for use in illuminating a physical space used by humans.
